(19) United States
(12) Patent Application Publication
(10) Pub. No.: US 2025/0218528 A1
(43) Pub. Date: Jul. 3, 2025

(54) READ DISTURB CHARGE LOSS HANDLING

(71) Applicant: Micron Technology, Inc., Boise, ID (US)

(72) Inventors: Murong Lang, San Jose, CA (US); Zhongguang Xu, San Jose, CA (US); Yu-Chung Lien, San Jose, CA (US); Ching-Huang Lu, Fremont, CA (US); Zhenming Zhou, San Jose, CA (US)

(21) Appl. No.: 19/000,357

(22) Filed: Dec. 23, 2024

Related U.S. Application Data
(60) Provisional application No. 63/617,328, filed on Jan. 3, 2024.

(51) Int. Cl. G11C 29/46; G11C 29/12; G11C 29/42

(52) U.S. Cl. CPC G11C 29/46; G11C 29/1201; G11C 29/42; G11C 2029/1202

(57) ABSTRACT

Methods, systems, and devices for read disturb charge loss handling are described. A memory system may be configured to perform a scan to identify errors from voltage threshold shift, due to performing read operations at high temperatures. The scan may be initiated based on detecting an operating temperature of the memory system and that a memory die of the memory system is unreliable. The memory system may determine a frequency for performing the scan, and perform the scan based on satisfying a threshold associated with the frequency. The scan may include scanning pages associated with word lines to determine whether a quantity of errors satisfies a threshold. After satisfying the threshold, the memory system may fold a block associated with the quantity of errors. In some examples, the pages scanned may be selected based on a priority level defined by a type of memory cells associated with the word lines.

### CROSS REFERENCE

The present application for patent claims priority to U.S. Patent Application No. 63/617,328 by Lang et al., entitled “READ DISTURB CHARGE LOSS HANDLING,” filed Jan. 3, 2024, which is assigned to the assignee hereof, and which is expressly incorporated by reference in its entirety herein.

### TECHNICAL FIELD

The following relates to one or more systems for memory, including read disturb charge loss handling.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not- and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports read disturb charge loss handling in accordance with examples as disclosed herein.

FIG. 2 shows an example of a process flow that supports read disturb charge loss handling in accordance with examples as disclosed herein.

FIG. 3 shows an example of a process flow that supports read disturb charge loss handling in accordance with examples as disclosed herein.

FIG. 4 shows a block diagram of a memory device that supports read disturb charge loss handling in accordance with examples as disclosed herein.

FIG. 5 shows a flowchart illustrating a method or methods that support read disturb charge loss handling in accordance with examples as disclosed herein.

### DETAILED DESCRIPTION

Memory systems may be configured to perform read operations under various conditions, including in relatively high temperatures. However, performing read operations at high temperatures (e.g., above a threshold associated with operation of the memory system) may increase read stress on memory cells of the memory system, resulting in charge loss of the memory cells, among other examples. In some cases, amplified read stress at high temperatures may cause voltage threshold levels associated with the memory cells to shift. For example, read stress may cause high voltage threshold level downshift, which may reduce a read window budget (e.g., RWB) between voltage thresholds. In some such examples, reducing a read window budget may cause difficulties ascertaining a logic state stored at an associated memory cell, resulting in errors during a read operation on the memory cell, among other reliability failings. High temperatures may affect memory dies of the memory system differently, such that some memory dies may experience relatively more read stress while performing read operations at high temperatures. Techniques for determining read stress, a corresponding downshift in voltage threshold levels, or both, may be beneficial to improve read operations at high temperatures.

In accordance with examples as described herein, a memory system may be configured to perform a read disturb charge loss (RDCL) scan to identify errors resulting from voltage threshold shift or charge loss due to performing read operations at high temperatures. The RDCL scan may be initiated based on detecting that an operating temperature of the memory system (e.g., or memory die) satisfies a threshold temperature, or based on determining that a memory die (e.g., subjected to the read operation) is weak (e.g., associated with reliability failures), or a combination thereof. In some cases, the memory system may identify operating parameters associated with the memory die (e.g., a program erase count (PEC), an operating temperature, other operating parameters, or a combination thereof) to determine a frequency for performing the RDCL scan, and the memory system may perform the RDCL scan based on a quantity of access operations satisfying a threshold associated with the frequency. The RDCL scan may include scanning pages of word lines to determine whether a quantity of errors satisfies a threshold. In some examples, the pages scanned may be selected based on a priority level of the respective page, where the priority level may be based on the type of memory cells associated with the pages (e.g., quad-level cells (QLCs), triple-level cells (TLCs), multi-level cells (MLCs), single-level cells (SLCs), among other types of memory cells). In some examples, the word lines may be selected based on a strength (e.g., reliability) of the word lines, or the word lines may be selected randomly from unprogrammed word lines, randomly from victim word lines, or based on the word lines being maintained in a list. In some cases, the RDCL scan may determine the quantity of errors satisfies the threshold, and the memory system may fold the block associated with the quantity of errors. Performing the RDCL scan may improve a reliability of the memory system by identifying errors resulting from voltage threshold shift or charge loss due to performing read operations at high temperatures, among other benefits.

In addition to applicability in memory systems described herein, techniques for read disturb charge loss handling may be generally implemented to improve security and/or authentication features of various electronic devices and systems. As the use of electronic devices for handling private, user, or other sensitive information has become even more widespread, electronic devices and systems have become the target of increasingly frequent and sophisticated attacks. Further, unauthorized access or modification of data in security-critical devices such as vehicles, healthcare devices, and others may be especially concerning. Implementing the techniques described herein may improve the security of electronic devices and systems by identifying error resulting from voltage threshold shift or charge loss, which may improve reliability of the electronic devices, among other benefits.

Features of the disclosure are illustrated and described in the context of systems, devices, and circuits. Features of the disclosure are further illustrated and described in the context of process flows and flowcharts.

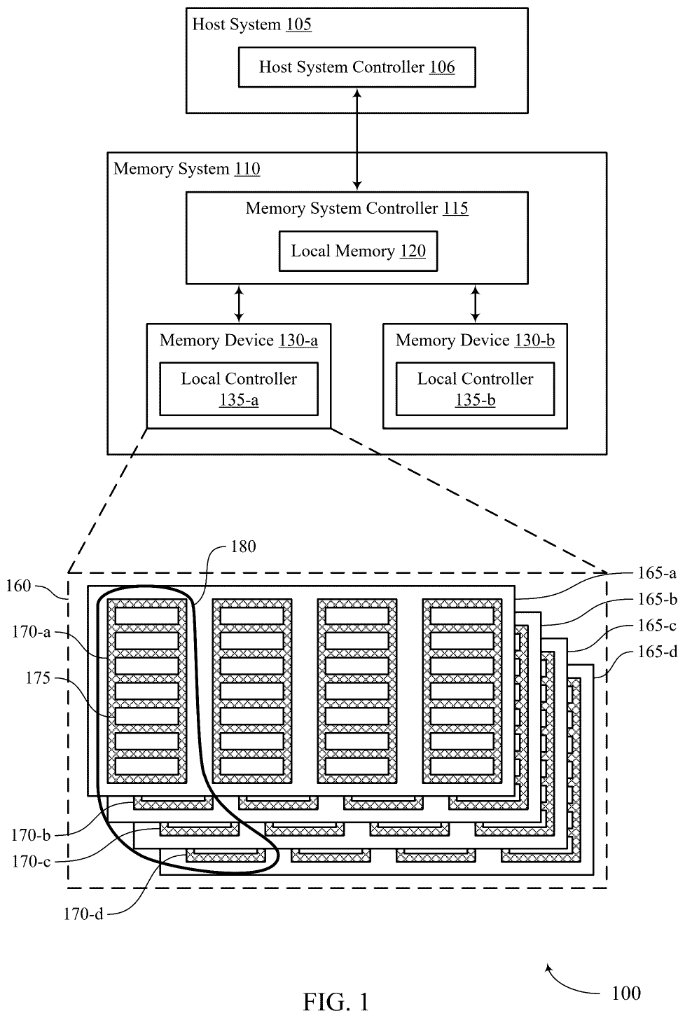

FIG. 1 shows an example of a system 100 that supports read disturb charge loss handling in accordance with examples as disclosed herein. The system 100 includes a host system 105 coupled with a memory system 110. The system 100 may be included in a computing device such as a desktop computer, a laptop computer, a network server, a mobile device, a vehicle (e.g., airplane, drone, train, automobile, or other conveyance), an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells. In some cases, operating conditions of the memory system 110 may affect reliability of dies 160. For example, relatively high operating temperatures of the memory system 110 may adversely affect reliability of the die 160. In some such cases, some dies 160 may experience relatively more reliability failures than other dies 160 at high temperatures based on a location or degradation of the dies 160.

In some cases, a NAND memory device 130 may include memory cells configured to each store one bit of information, which may be referred to as SLCs. Additionally, or alternatively, a NAND memory device 130 may include memory cells configured to each store multiple bits of information, which may be referred to as MLCs if configured to each store two bits of information, as TLCs if configured to each store three bits of information, as QLCs if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, a quantity of pages 175 associated with a memory cell may be based on a type of the memory cell, where the type may be QLC, TLC, MLC, or SLC, among other options. For example, a QLC may be associated with 4 pages including a top page, an extra page, an upper page, and a lower page. Likewise, a TLC may be associated with 3 pages including an extra page, an upper page, and a lower page. Additionally, an MLC may be associated with 2 pages including an upper page and a lower page. Finally, an SLC may be associated with 1 page, which is a lower page. In some examples, the quantity of pages 175 associated with each memory cell may correspond to a quantity of bits that may be stored by the respective memory cell.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, to update some data within a block 170 while retaining other data within the block 170, the memory device 130 may copy the data to be retained to a new block 170 and write the updated data to one or more remaining pages of the new block 170. The memory device 130 (e.g., the local controller 135) or the memory system controller 115 may mark or otherwise designate the data that remains in the old block 170 as invalid or obsolete and may update a logical-to-physical (L2P) mapping table to associate the logical address (e.g., LBA) for the data with the new, valid block 170 rather than the old, invalid block 170.

In some cases, L2P mapping tables may be maintained and data may be marked as valid or invalid at the page level of granularity, and a page 175 may contain valid data, invalid data, or no data. Invalid data may be data that is outdated, which may be due to a more recent or updated version of the data being stored in a different page 175 of the memory device 130. Invalid data may have been previously programmed to the invalid page 175 but may no longer be associated with a valid logical address, such as a logical address referenced by the host system 105. Valid data may be the most recent version of such data being stored on the memory device 130. A page 175 that includes no data may be a page 175 that has not been written to or that has been erased.

In some cases, a memory system controller 115 or a local controller 135 may perform operations (e.g., as part of one or more media management algorithms) for a memory device 130, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105).

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

The system 100 may include any quantity of non-transitory computer readable media that support read disturb charge loss handling. For example, the host system 105 (e.g., a host system controller 106), the memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

In some cases, the memory system 110 may be configured to perform read operations on the memory cells. For example, the memory system 110 may receive a read command from the host system 105 indicating to read one or more memory cells of the memory system 110. In some such examples, reading a memory cell may include sensing a voltage stored at the memory cell and comparing the sensed voltage to one or more thresholds to determine a logic state of the memory cell. In some cases, a quantity of thresholds to which the sensed voltage may be compared is based on a quantity of bits stored by the memory cell. For example, a voltage sensed from an SLC may be compared to two threshold voltages to determine the logic state (e.g., 0 or 1) of the SLC. Likewise, a voltage sensed from an MLC may be compared to four threshold voltages to determine the logic state (e.g., 11, 01, 00, or 10) of the MLC. Additionally, a voltage sensed from an TLC may be compared to eight threshold voltages to determine the logic state (e.g., 111, 011, 001, 101, 100, 000, 010, or 110) of the TLC. Finally, a voltage sensed from an QLC may be compared to 16 threshold voltages to determine the logic state (e.g., 1111, 0111, 0011, 1011, 1001, 0001, 0101, 1101, 1100, 0100, 0000, 1000, 1010, 0010, 0110, or 1110) of the QLC.

In some cases, a quantity of threshold voltages associated with a memory cell may affect a read window budget of the memory cell. A read window budget may be defined by a voltage differential between threshold voltages, such that a relatively higher quantity of threshold voltages may cause a relatively smaller read window budget. That is, an inverse relationship may be present between a quantity of bits that the memory cell is configured to store and a read window budget of the memory cell. Likewise, as a quantity of pages 175 associated with the memory cell (e.g., a storable quantity of bits) increases, a read window budget of the memory cell may decrease. For example, an SLC may have a relatively greater read window budget than a QLC. In some cases, a relatively smaller read window budget may cause difficulties ascertaining a logic state of the associated memory cell. For example, it may be more difficult to determine a logic state of a QLC than an SLC. In some such cases, a memory cell may be more likely to produce errors during a read operation.

In some cases, operating conditions of the memory system 110 may affect read stress produced during performing a read operation. For example, performing read operations at high operating temperatures of the memory system 110 may increase read stress on memory cells subjected to the read operation, resulting in charge loss (e.g., voltage degradation, electron detrapping and leaking) of the memory cells. In some cases, the increased read stress (e.g., at high temperatures) may cause the voltage thresholds associated with the memory cells to shift. For example, the increased read stress may cause relatively high downshift of the voltage thresholds, which may reduce a read window budget between the voltage thresholds. That is, there may be a corollary relationship between voltage threshold shift and high operating temperatures of the memory system 110. In some such examples, this may cause increased difficulty for determining logic states stored at the memory cells, resulting in errors during reading the memory cells, among other reliability failings.

In some cases, memory cells associated with some word lines may be relatively more affected by high temperatures. For example, high temperatures may adversely affect read stress on memory cells associated with word lines that are associated with reliability difficulties. As such, errors may be more frequently detected in data stored in memory cells associated with such word lines.

In some cases, determining read stress, or the resulting downshift in voltage threshold levels, or both, may provide for a memory system to reduce or otherwise mitigate the effects of read stress. For example, identifying relatively high read stress in a block of memory cells may enable the memory system to fold data from the block of memory cells to a block with relatively lower read stress. However, some memory systems may not perform scans to determine read stress for read operations performed at high temperatures. Additionally, or alternatively, in some memory systems, scans to determine read stress may not be performed at a granularity which supports mitigating the effects of read stress at a targeted granularity. For example, scans may not be implemented for specific pages 175 that may better indicate read stress.

In accordance with examples as described herein, the memory system 110 may be configured to perform an RDCL scan to identify errors resulting from voltage threshold shift or charge loss due to performing read operations at high temperatures. The RDCL scan may be initiated based on detecting that an operating temperature of the memory system 110 (e.g., or die 160) satisfies a threshold (e.g., a threshold temperature), or based on determining that a die 160 (e.g., subjected to the read operation) is weak (e.g., associated with reliability failures), or a combination thereof. In some cases, the memory system 110 may identify operating parameters associated with the die 160 (e.g., PEC), operating temperature, other operating parameters, or a combination thereof) to determine a frequency for performing the RDCL scan, and perform the RDCL scan based on a quantity of access operations satisfying a threshold associated with the frequency. The RDCL scan may include scanning pages 175 of word lines to determine whether a quantity of errors satisfies a threshold. In some examples, the pages scanned may be selected based on a priority level of the respective page 175, where the priority level is defined by the type of memory cells associated with the pages 175 (e.g., QLCs, TLCs, MLCs, SLCs). In some examples, the word lines may be selected based on a strength (e.g., reliability) of the word lines, randomly from unprogrammed word lines, randomly from victim word lines, or based on the word lines being maintained in a list. In some cases, the RDCL scan may determine the quantity of errors satisfies the threshold, and the memory system 110 may fold the block associated with the quantity of errors. Performing the RDCL scan may improve a reliability of the memory system 110 by identifying errors resulting from voltage threshold shift or charge loss due to performing read operations at high temperatures, among other benefits.

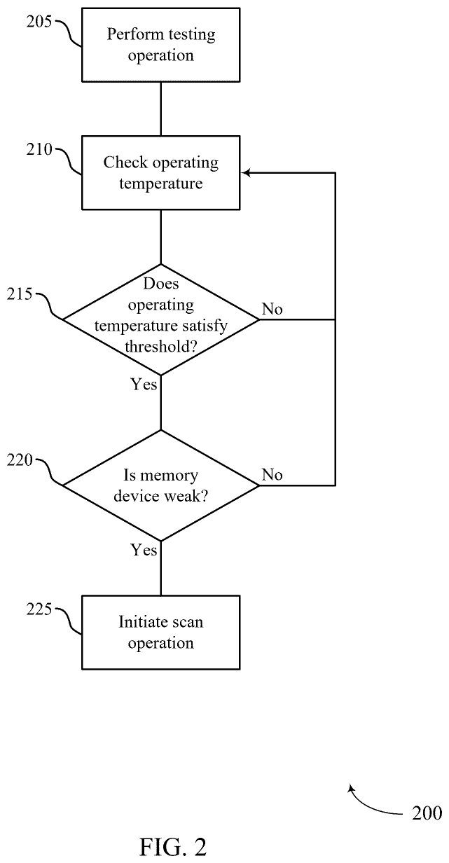

FIG. 2 shows an example of a process flow 200 that supports read disturb charge loss handling in accordance with examples as disclosed herein. The process flow 200 may illustrate aspects or operations of a system, which may be an example of a system 100, as described with reference to FIG. 1. For example, the process flow 200 may be implemented by a memory system 110, as described with reference to FIG. 1. In the following description of the process flow 200, the methods, techniques, processes, and operations may be performed in different orders or at different times. Further, some operations may be left out of the process flow 200, or other operations may be added to the process flow 200.

Aspect of the process flow 200 described at the memory system 110 may be implemented by a memory system controller 115 or by a host system 105, as described with reference to FIG. 1. Additionally, or alternatively, aspects of the process flow 200 may be implemented as instructions stored in memory (e.g., firmware). For example, the instructions, if executed by a controller (e.g., a host system controller, the memory system controller 115, a local controller 135), may cause the controller to perform the operations of the process flow 200. The process flow 200 may support operations for determining whether to perform a scan operation for identifying errors resulting from voltage threshold shift due to performing read operations at high temperatures.

At 205, a testing operation may be performed. The memory system 110 may perform the testing operation (e.g., probe) to determine the reliability (e.g., health, strength) of one or more dies 160 of the memory system, as described with reference to FIG. 1. Performing the testing operation may include determining whether a quantity of errors detected at one or more dies 160 satisfies one or more thresholds (e.g., each threshold being a threshold quantity of errors). For example, if the quantity of errors at a die 160 does not satisfy a threshold, the die 160 may be considered reliable (e.g., sufficiently reliable).

In some cases, performing the testing operation may include performing an error detection operation at one or more locations of one or more dies 160, such that the error detection operation may determine a quantity of errors in the one or more dies 160. For example, the error detection operation may include detecting a quantity of errors in data stored in the one or more dies 160 or one or more portions of one or more dies 160, where the one or more portions may be one or more blocks, one or more word lines, one or more rows of memory cells, one or more pages, or a combination thereof (e.g., among other components of the one or more dies 160). In some cases, the testing operation may be performed to categorize a strength of the one or more dies 160. For example, if the quantity of errors at a die 160 satisfies a threshold, the die 160 may be considered a weak die. Whereas, if the quantity of errors at the die 160 does not satisfy the threshold, the die 160 may be considered a strong die.

In some cases, the testing operation may be performed prior to performing other steps of the process flow 200. For example, the testing operation may be performed during initialization (e.g., power on) of the memory system 110 or during manufacturing of the memory system 110 (e.g., within a testing environment). In some examples, the testing operation may be performed based on a command from the host system 105. In other examples, the testing operation may be performed periodically (e.g., based on a quantity of access operations or a quantity of time).

At 210, an operating temperature of the memory system 110 may be checked (e.g., monitored, detected). In some cases, checking the operating temperature may include selecting a die 160 of the memory system 110 and checking the operating temperature of the selected die 160. In some examples, the temperature of the memory system 110, or the selected die 160, may be continuously monitored (e.g., by a temperature sensor of the memory system 110), then polled to check the operating temperature. In some implementations, the operating temperature may be checked periodically, such that the operating temperature is checked based on a threshold quantity of access operations being performed since a last scan of the operating temperature for a respective die, or based on satisfying a threshold quantity of time since a last scan of the operating temperature for a respective die, or both. In some such implementations, a period for checking the operating temperature may be based on the reliability of the selected die 160, as determined at step 205 of the process flow 200. For example, the period for checking the operating temperature of a weak die may be less than the period for checking the operating temperature of a strong die, such that the weaker die may be checked more frequently than the stronger die. In other implementations, the operating temperature may be checked based on receiving a command (e.g., from the host system 105).

At 215, the operating temperature may be compared to a threshold (e.g., a threshold temperature) to determine whether the operating temperature satisfies the threshold. For example, the memory system 110 (e.g., the memory system controller 115) may compare the operating temperature of the selected die 160 with the threshold to determine whether the operating temperature of the selected die 160 satisfies (e.g., is greater than) the threshold. In some implementations, the operating temperature of each die 160 of the memory system 110 may be compared with a respective threshold to determine whether the operating temperature of each die 160 satisfies the respective threshold for that die. In some implementations, determining the operating temperature satisfies the threshold may include determining the operating temperature is within a range of temperatures (e.g., defined by the threshold). In some cases, the operating temperature may satisfy the threshold and the process flow 200 may continue to step 220. However, in other cases, the operating temperature may not satisfy the threshold and the process flow 200 may revert back to step 210.

At 220, the memory system 110 may determine whether the selected die 160 is a weak die based on (e.g., in response to, after) determining the operating temperature of the selected die 160 satisfies the threshold. The memory system 110 may determine whether the selected die 160 is a weak die based on identifying a categorization of the selected die 160 resulting from the testing operation at step 205 of the process flow 200. In some cases, if the memory system 110 determines the selected die 160 is a weak die (e.g., based on the testing operation), the process flow 200 may continue to step 225. However, in other cases, if the memory system 110 determines the selected die 160 is a strong die (e.g., based on the testing operation), the process flow 200 may revert back to step 210. That is, the memory system 110 may continue to check the operating temperature of the selected die 160 and may refrain from performing further operations. Additionally, or alternatively, if the selected die 160 is a strong die, the memory system 110 may select another die 160 of the memory system 110, and the operating temperature of the other die 160 may be checked at 210.

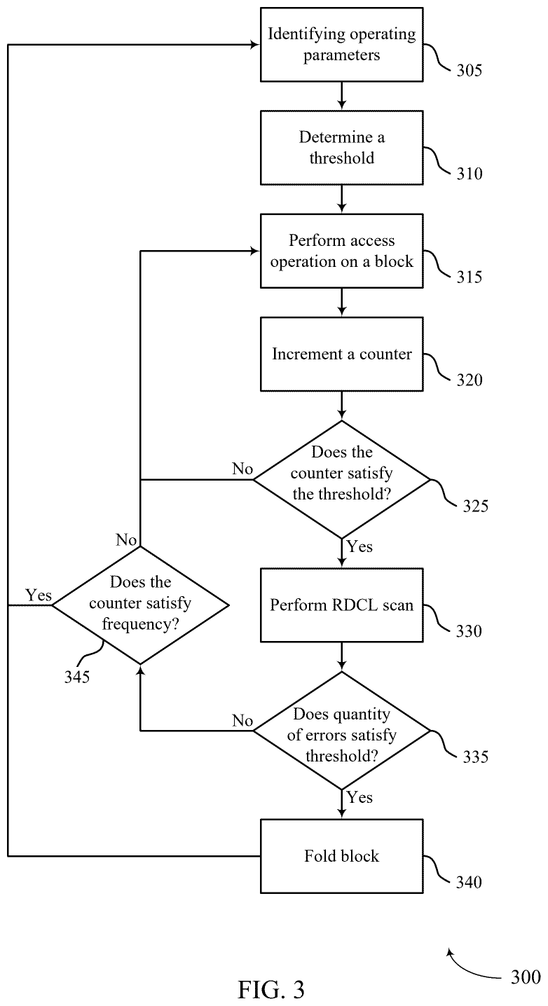

At 225, a scan operation may be initiated. The memory system 110 may initiate the scan operation based on determining the selected die 160 has an operating temperature satisfying the threshold, and that the selected die 160 is a weak die. Thus, the scan operation may be performed on the selected die 160. The scan operation may include operations to identify errors resulting from voltage threshold shift due to performing read operations at high temperatures. Operations of the scan operation may be described in further details elsewhere herein, including with reference to FIG. 3. For example, the scan operation may include the operations of a process flow 300, as described with reference to FIG. 3.

FIG. 3 shows an example of a process flow 300 that supports read disturb charge loss handling in accordance with examples as disclosed herein. The process flow 300 may illustrate aspects or operations of a system, which may be an example of a system 100, as described with reference to FIG. 1. For example, the process flow 300 may be implemented by a memory system 110, as described with reference to FIG. 1. In the following description of the process flow 300, the methods, techniques, processes, and operations may be performed in different orders or at different times. Further, some operations may be left out of the process flow 300, or other operations may be added to the process flow 300. The process flow 300 may illustrate operations resulting from process flow 200. For example, step 305 of the process flow 300 may be preceded by step 225 of the process flow 300, in some examples, or may otherwise be performed in parallel with, before, or after one or more steps of the process flow 300.

Aspect of the process flow 300 described at the memory system 110 may be implemented by a memory system controller 115 or by a host system 105, as described with reference to FIG. 1. Additionally, or alternatively, aspects of the process flow 300 may be implemented as instructions stored in memory (e.g., firmware). For example, the instructions, if executed by a controller (e.g., a processor, a host system controller, the memory system controller 115, a local controller 135), may cause the controller to perform the operations of the process flow 300. The process flow 300 may support operations for determining whether to perform a scan operation for identifying errors resulting from voltage threshold shift due to performing read operations at high temperatures. The process flow 300 may be performed on a die 160 of the memory system 110, which may be selected during step 210 of the process flow 200. In some cases, the process flow 300 may also be implemented (e.g., simultaneously, sequentially) for one or more other dies 160 of the memory system 110.

At 305, operating parameters of the die 160 may be identified. The memory system 110 may identify the operating parameters of the die 160 based on monitoring (e.g., recorded, sensed by one or more sensors) the operating parameters and checking (e.g., polling) the monitored operating parameters. In some cases, the memory system 110 may identify the operating parameters based on initiating a scan operation, as described with reference to step 225 of the process flow 200. The operating parameters may include a PEC of the die 160, an operating temperature of the die 160, one or more other operating parameters, or a combination thereof. In some cases, the PEC may be an average PEC across one or more blocks of the die 160.

At 310, a threshold may be determined. For example, the memory system 110 may determine a frequency (e.g., a periodicity, a window size, or some other frequency) for performing an RDCL scan based on the operating parameters of the die 160. In some cases, the frequency for performing the RDCL may be correlated to a magnitude of the operating parameters. For example, the frequency may be relatively low (e.g., infrequent RDCL scans) if the PEC is relatively low, or the frequency may be relatively high (e.g., frequent RDCL scans) if the PEC is relatively high. Likewise, the frequency may be relatively low if the operating temperature is relatively low, or the frequency may be relatively high if the PEC is relatively high. In some cases, the frequency may be defined by access operations, such that a magnitude of the frequency may be a quantity of access operations. The memory system 110 may use the frequency to determine the threshold. The threshold may be set such that satisfying the threshold may trigger the RDCL scan. In some cases, the threshold may be determined by generating a random value (e.g., a positive integer value, URN) between one and a magnitude of the frequency. For example, the threshold may be a random value greater than or equal to one and less than or equal to a quantity of access operations associated with the frequency (e.g., 1≤URN≤W, where URN corresponds to the random value and W corresponds to a window size).

In some cases, at 310, the memory system 110 may reset a counter (e.g., a read counter). The counter may maintain a count value corresponding to a quantity of access operations performed on a block of the die 160. The memory system 110 may reset the counter based on determining the threshold.

At 315, in some cases, an access operation may be performed on the block of the die 160. In some cases, the access operation may be a read operation performed on the block. In some such cases, the memory system 110 may receive a read command (e.g., from the host system 105) including an address of the block, and the memory system 110 may read data from the address of the block. For example, the read command may indicate a page of the block, and the read operation may be performed to read data from the page. In some cases, one or more additional access operations may be performed on other blocks of the die 160.

Additionally, or alternatively, although not pictured in FIG. 3, in some examples, a read command may not be received for the block of the memory die. For example, within a threshold time period, no read command may be received. If no command is received within a threshold time, the memory system 110 may end the scan operation.

At 320, if the access operation is performed, the counter may be incremented based on performing the access operation. The counter may be incremented according to performing access operations on the block, such that the count value may be increased (e.g., by one) for each access operation performed on the block. In some cases, each block may include a respective counter, such that each time an access operation is performed on a block of the die 160, a respective counter may be incremented. In some cases, the counter may be a page counter, configured to increment each time a page of the block is read (e.g., or otherwise accessed).

At 325, after incrementing the counter, the counter may be compared to the threshold (e.g., the threshold determined at step 310 of the process flow 300). The count value of the counter may be compared to the threshold to determine whether the count value satisfies the threshold. For example, the counter may indicate a quantity of access operations performed on the block, and the quantity of access operations may be compared to the threshold to determine if the quantity of access operation satisfies (e.g., is equal to or greater than) the threshold. In some cases, the counter may satisfy the threshold, and the process flow 300 may continue to step 330. However, in other cases, if the counter does not satisfy (e.g., is less than) the threshold, the process flow 300 may revert back to step 315. For example, if the counter is less than the threshold, the count value may be maintained and additional access operations may be performed, with the counter incremented for each subsequent access operation on the block until the count value satisfies the threshold.

At 330, the RDCL scan may be performed. The memory system 110 may perform the RDCL scan based on the counter satisfying the threshold. The RDCL scan may identify a quantity of errors of the block. In some cases, the RDCL scan may include scanning pages of the block. The pages may be associated with memory cells, where the memory cells share one or more word lines. Thus, the pages may be selected based on the one or more word lines that are selected.

In some cases, the one or more word lines selected for scanning may be selected based on the one or more word lines being weak word lines. That is, the one or more word lines may be randomly selected from word lines categorized as weak word lines during the testing operation at step 205 of the process flow 200. In some such cases, the one or more word lines may be weak word lines based on determining a quantity of errors at the one or more word lines satisfies a threshold associated with weak word lines. The one or more word lines may be selected because weak word lines may be prioritized by the RDCL scan.

In some cases, the one or more word lines selected for scanning may be selected from victim word lines of the access operation performed at step 315 of the process flow 300. That is, the one or more word lines may be randomly selected from victim word lines which are adjacent to or nearby one or more word lines accessed during the access operation. For example, a first word line may be accessed at step 315 of the process flow 300, and a second word line (e.g., numerically below the first word line) and a third word line (e.g., numerically above the first word line) may be victim word lines of the first word line based on being adjacent to (e.g., or nearby) the first word line. In such an example, the word line selected for scanning by the RDCL scan may be randomly selected from the second word line or third word line. In some implementations, if the first word line that is accessed at step 315 is the first word line of the block, the word line selected for scanning by the RDCL scan may be the third word line that is numerically above the first word line (e.g., based on no word lines being present in the block that are numerically below the first word line). In other implementations, if the first word line is the last word line of the block, the word line selected for scanning by the RDCL scan may be the second word line that is numerically below the first word line (e.g., based on no word lines being present in the block that are numerically above the first word line).

In some cases, the one or more word lines selected for scanning may be selected from a predetermined list of word lines (e.g., a read disturb ranking of mandatory word lines) stored at the memory system 110. The list of word lines may include word lines determined as relatively susceptible to reliability failures. In some examples, the list of word lines may be generated based on physical characteristics of the die 160, or based on identifying weak word lines during the testing operation at step 205 of the process flow 200. In some implementations, the one or more word lines selected for scanning may be selected (e.g., randomly selected) from unprogrammed word lines in the predetermined list of word lines. Unprogrammed word lines may include word lines with any quantity of one or more memory cells that are not programmed. In other implementations, the one or more word lines selected for scanning may be selected (e.g., randomly selected) from programmed word lines in the predetermined list of word lines. In some implementations, the one or more word lines selected for scanning may be selected (e.g., randomly selected) from unprogrammed word lines in the open block of the die 160.

In some cases, the pages selected for scanning may be based on a priority rating of the pages, where the priority rating is based on a quantity of bits stored in the memory cells associated with the selected word lines. In some cases, the priority rating may be based on a raw bit error rate (RBER) of the pages, such that pages associated with a relatively higher RBER may have a relatively higher priority rating. In some such cases, the RBER may be based on the quantity of bits stored in the memory cells associated with the pages. For example, for QLCs, the RDCL scan may scan a lower page and a top page of the QLCs, prioritizing the top page. For TLCs, the RDCL scan may scan a lower page and an extra page of the TLCs, prioritizing the extra page. For MLCs, the RDCL scan may scan a lower page and an upper page of the MLCs, prioritizing the lower page. For SLCs, the RDCL scan may scan a lower page of the SLCs.

At 335, the quantity of errors identified by the RDCL scan may be compared to a threshold quantity of errors. For example, the RDCL scan may identify a quantity of errors based on scanning one or more selected pages associated with one or more selected word lines. The identified quantity of errors may be compared with a threshold quantity of errors to determine whether the identified quantity of errors satisfies (e.g., is greater than or equal to) the threshold quantity of errors. In some cases, the memory system 110 may determine the identified quantity of errors satisfies the threshold quantity of errors, and the process flow 300 may continue to step 340. In other cases, the memory system 110 may determine the identified quantity of errors does not satisfy the threshold quantity of errors, and the process flow 300 may continue to step 345.

At 340, if the identified quantity of errors satisfies the threshold quantity of errors, the block may be folded. The memory system 110 may fold the block based on determining the quantity of errors identified by the RDCL scan satisfies the threshold quantity of errors. Folding the block may include transferring data from the block to another block of the die 160. In some cases, folding the block may include identifying valid data (e.g., data not associated with errors) and invalid data (e.g., data associated with errors) from the block, and transferring the valid data to another block of the die 160. The invalid data may be erased or replaced (e.g., overwritten) as a result of transferring the valid data to another block of the die 160. In some examples, any data remaining in the block after folding the block may be erased or replaced. In some implementations, after folding the block, the block may be marked (e.g., recorded) as being folded, or marked as a weak block. In some cases, after folding the block, the process flow 300 may revert back to step 305.

At 345, if the identified quantity of errors does not satisfy the threshold quantity of errors, the counter may be compared to the frequency (e.g., the frequency for performing the RDCL, which may be correlated to the magnitude of the operating parameters) determined at step 310 of the process flow 300. The memory system 110 may compare the counter to the frequency to determine whether the counter satisfies (e.g., is equal to) the frequency. For example, the frequency may be a quantity of access operations, and comparing the counter to the frequency may include determining whether the quantity of access operations performed on the block is equal to the quantity of access operation associated with the frequency. In some cases, the memory system 110 may determine the counter does not satisfy the frequency, and the process flow 300 may revert back to step 315. In some such cases, the memory system 110 may continue performing access operations on the block until the counter satisfies the frequency, after which the process flow 300 may continue to step 330. However, in other cases, the memory system 110 may determine the counter satisfies the frequency, and the process flow 300 may revert back to step 305. In some such cases, after returning to step 305, the memory system 110 may select another block of the die 160 to perform the process flow 300 on. In other such cases, after returning to step 305, the memory system 110 may revert back to step 210 of the process flow 200, to select another die 160 to perform the process flow 200 and the process flow 300 on.

In accordance with examples as described herein, performing the process flow 200 and the process flow 300 may support identifying errors resulting from voltage threshold shift due to performing read operations at high temperatures. Identifying errors resulting from voltage threshold shift may help prevent uncorrectable errors in the memory system 110, thereby improving reliability of the memory system 110. Additionally, identifying errors resulting from voltage threshold shift may enable data stored in weak areas of the memory system 110 to be transferred and maintained in stronger areas of the memory system 110, thereby improving error control and data retention capabilities of the memory system 110, among other advantages.

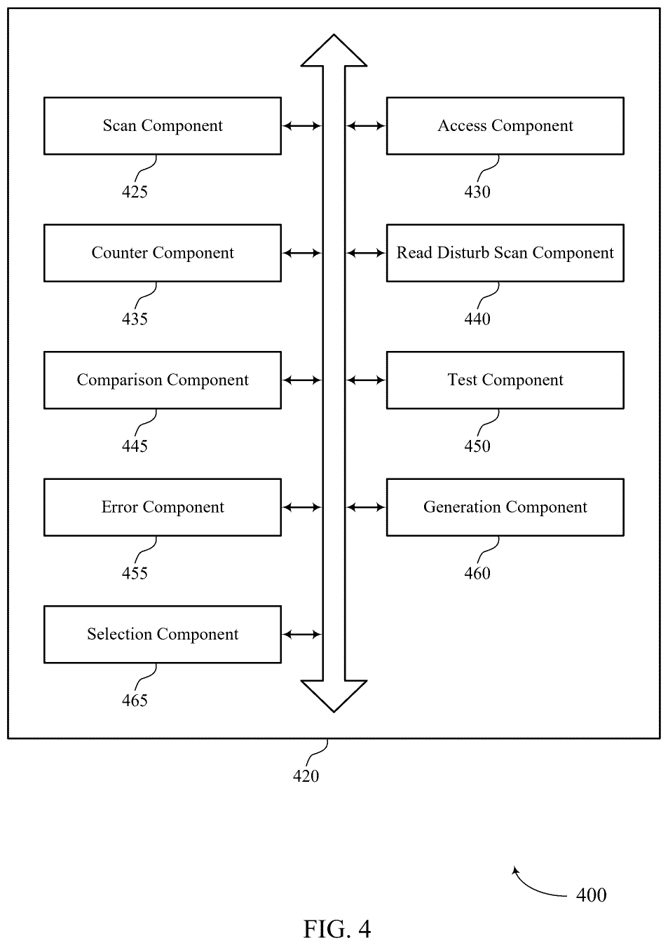

FIG. 4 shows a block diagram 400 of a memory device 420 that supports read disturb charge loss handling in accordance with examples as disclosed herein. The memory device 420 may be an example of aspects of a memory device as described with reference to FIGS. 1 through 3. The memory device 420, or various components thereof, may be an example of means for performing various aspects of read disturb charge loss handling as described herein. For example, the memory device 420 may include a scan component 425, an access component 430, a counter component 435, a read disturb scan component 440, a comparison component 445, a test component 450, an error component 455, a generation component 460, a selection component 465, or any combination thereof. Each of these components, or components of subcomponents thereof (e.g., one or more processors, one or more memories), may communicate, directly or indirectly, with one another (e.g., via one or more buses).

The scan component 425 may be configured as or otherwise support a means for initiating a scan operation for a block of the memory device. The access component 430 may be configured as or otherwise support a means for performing an access operation on the block based at least in part on one or more operating parameters associated with the memory device. The counter component 435 may be configured as or otherwise support a means for adjusting a counter associated with the block based at least in part on performing the access operation. The read disturb scan component 440 may be configured as or otherwise support a means for performing, as part of the scan operation, a read disturb scan for the block based at least in part on the counter satisfying a threshold, where the threshold is associated with a frequency for the scan operation, and where the one or more operating parameters include the frequency.

In some examples, the comparison component 445 may be configured as or otherwise support a means for comparing a temperature of the memory device with a threshold temperature, where initiating the scan operation is based at least in part on the temperature of the memory device satisfying the threshold temperature.

In some examples, the test component 450 may be configured as or otherwise support a means for performing a test operation on the memory device, the test operation associated with a quantity of errors of the memory device, where initiating the scan operation is based at least in part on the quantity of errors of the memory device detected during the test operation satisfying a threshold quantity of errors.

In some examples, to support performing the read disturb scan, the read disturb scan component 440 may be configured as or otherwise support a means for scanning one or more pages for one or more word lines of the block, where the one or more pages are scanned based at least in part on a priority rating of the one or more pages. In some examples, to support performing the read disturb scan, the error component 455 may be configured as or otherwise support a means for identifying a quantity of errors associated with voltage thresholds of the one or more pages based at least in part on the scanning.

In some examples, the priority rating of the one or more pages is based at least in part on a quantity of bits stored in one or more memory cells associated with the one or more word lines.

In some examples, to support scanning the one or more pages, the read disturb scan component 440 may be configured as or otherwise support a means for scanning a top page and a lower page of each of the one or more word lines based at least in part on the one or more memory cells being quad-level cells.

In some examples, to support scanning the one or more pages, the read disturb scan component 440 may be configured as or otherwise support a means for scanning an extra page and a lower page of each of the one or more word lines based at least in part on the one or more memory cells being triple-level cells.

In some examples, to support scanning the one or more pages, the read disturb scan component 440 may be configured as or otherwise support a means for scanning an upper page and a lower page of each of the one or more word lines based at least in part on the one or more memory cells being multi-level cells.

In some examples, the selection component 465 may be configured as or otherwise support a means for selecting, from among a plurality of word lines of the block, the one or more word lines randomly based at least in part on a second quantity of errors previously detected at the one or more word lines.

In some examples, the selection component 465 may be configured as or otherwise support a means for selecting, from among a plurality of word lines of the block, the one or more word lines randomly based at least in part on at least one word line of the plurality of word lines of the block being unprogrammed.

In some examples, the selection component 465 may be configured as or otherwise support a means for selecting, from among a plurality of word lines of the block, the one or more word lines randomly based at least in part on the one or more word lines being adjacent to a word line selected during the access operation.

In some examples, the selection component 465 may be configured as or otherwise support a means for selecting, from among a plurality of word lines of the block, the one or more word lines based at least in part on the one or more word lines being maintained in a list of word lines stored at the memory device.

In some examples, the comparison component 445 may be configured as or otherwise support a means for comparing, based at least in part on performing the read disturb scan, a quantity of errors of the block with a threshold quantity of errors. In some examples, the access component 430 may be configured as or otherwise support a means for folding the block based at least in part on the quantity of errors satisfying the threshold quantity of errors.

In some examples, the comparison component 445 may be configured as or otherwise support a means for comparing, based at least in part on performing the scan operation, a quantity of errors of the block with a threshold quantity of errors. In some examples, the scan component 425 may be configured as or otherwise support a means for reinitiating the scan operation for a second block of the memory device based at least in part on the quantity of errors failing to satisfy the threshold quantity of errors.

In some examples, the generation component 460 may be configured as or otherwise support a means for generating a positive random value that is less than or equal to the frequency, where the threshold associated with the frequency corresponds to the positive random value.

In some examples, to support performing the access operation, the access component 430 may be configured as or otherwise support a means for receiving a read command for a page of the block. In some examples, to support performing the access operation, the access component 430 may be configured as or otherwise support a means for performing a read operation for the page of the block based at least in part on receiving the read command.

In some examples, the one or more operating parameters includes a program erase count, or a temperature of the memory device, or both.

In some examples, the described functionality of the memory device 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory device 420, or various components thereof, may be implemented at least in part by instructions (e.g., stored in memory, non-transitory computer-readable medium) executable by such at least one processor.

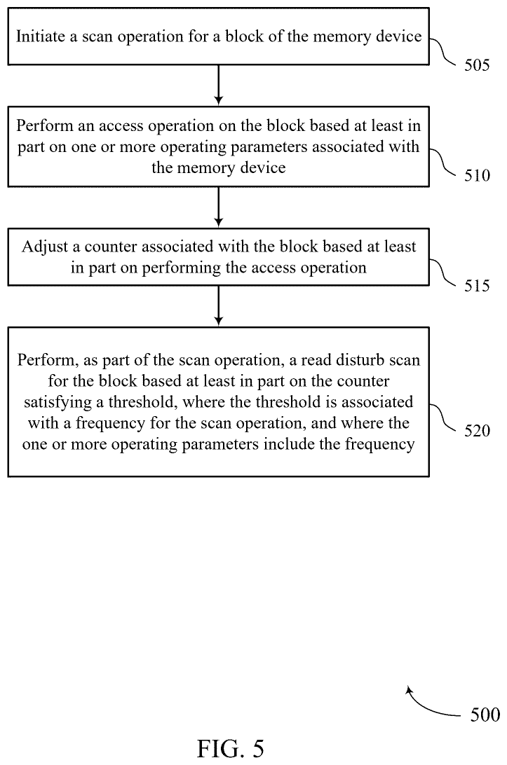

FIG. 5 shows a flowchart illustrating a method 500 that supports read disturb charge loss handling in accordance with examples as disclosed herein. The operations of method 500 may be implemented by a memory device or its components as described herein. For example, the operations of method 500 may be performed by a memory device as described with reference to FIGS. 1 through 4. In some examples, a memory device may execute a set of instructions to control the functional elements of the device to perform the described functions. Additionally, or alternatively, the memory device may perform aspects of the described functions using special-purpose hardware.

At 505, the method may include initiating a scan operation for a block of the memory device. In some examples, aspects of the operations of 505 may be performed by a scan component 425 as described with reference to FIG. 4.

At 510, the method may include performing an access operation on the block based at least in part on one or more operating parameters associated with the memory device. In some examples, aspects of the operations of 510 may be performed by an access component 430 as described with reference to FIG. 4.

At 515, the method may include adjusting a counter associated with the block based at least in part on performing the access operation. In some examples, aspects of the operations of 515 may be performed by a counter component 435 as described with reference to FIG. 4.

At 520, the method may include performing, as part of the scan operation, a read disturb scan for the block based at least in part on the counter satisfying a threshold, where the threshold is associated with a frequency for the scan operation, and where the one or more operating parameters include the frequency. In some examples, aspects of the operations of 520 may be performed by a read disturb scan component 440 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for initiating a scan operation for a block of the memory device; performing an access operation on the block based at least in part on one or more operating parameters associated with the memory device; adjusting a counter associated with the block based at least in part on performing the access operation; and performing, as part of the scan operation, a read disturb scan for the block based at least in part on the counter satisfying a threshold, where the threshold is associated with a frequency for the scan operation, and where the one or more operating parameters include the frequency.

Aspect 2: The method, apparatus, or non-transitory computer-readable medium of aspect 1, further including operations, features, circuitry, logic, means, or instructions, or any combination thereof for comparing a temperature of the memory device with a threshold temperature, where initiating the scan operation is based at least in part on the temperature of the memory device satisfying the threshold temperature.

Aspect 3: The method, apparatus, or non-transitory computer-readable medium of any of aspects 1 through 2, further including operations, features, circuitry, logic, means, or instructions, or any combination thereof for performing a test operation on the memory device, the test operation associated with a quantity of errors of the memory device, where initiating the scan operation is based at least in part on the quantity of errors of the memory device detected during the test operation satisfying a threshold quantity of errors.

Aspect 4: The method, apparatus, or non-transitory computer-readable medium of any of aspects 1 through 3, where performing the read disturb scan includes operations, features, circuitry, logic, means, or instructions, or any combination thereof for scanning one or more pages for one or more word lines of the block, where the one or more pages are scanned based at least in part on a priority rating of the one or more pages and identifying a quantity of errors associated with voltage thresholds of the one or more pages based at least in part on the scanning.

Aspect 5: The method, apparatus, or non-transitory computer-readable medium of aspect 4, where the priority rating of the one or more pages is based at least in part on a quantity of bits stored in one or more memory cells associated with the one or more word lines.

Aspect 6: The method, apparatus, or non-transitory computer-readable medium of any of aspects 4 through 5, where scanning the one or more pages includes operations, features, circuitry, logic, means, or instructions, or any combination thereof for scanning a top page and a lower page of each of the one or more word lines based at least in part on the one or more memory cells being quad-level cells.

Aspect 7: The method, apparatus, or non-transitory computer-readable medium of any of aspects 4 through 6, where scanning the one or more pages includes operations, features, circuitry, logic, means, or instructions, or any combination thereof for scanning an extra page and a lower page of each of the one or more word lines based at least in part on the one or more memory cells being triple-level cells.

Aspect 8: The method, apparatus, or non-transitory computer-readable medium of any of aspects 4 through 7, where scanning the one or more pages includes operations, features, circuitry, logic, means, or instructions, or any combination thereof for scanning an upper page and a lower page of each of the one or more word lines based at least in part on the one or more memory cells being multi-level cells.

Aspect 9: The method, apparatus, or non-transitory computer-readable medium of any of aspects 4 through 8, further including operations, features, circuitry, logic, means, or instructions, or any combination thereof for selecting, from among a plurality of word lines of the block, the one or more word lines randomly based at least in part on a second quantity of errors previously detected at the one or more word lines.

Aspect 10: The method, apparatus, or non-transitory computer-readable medium of any of aspects 4 through 9, further including operations, features, circuitry, logic, means, or instructions, or any combination thereof for selecting, from among a plurality of word lines of the block, the one or more word lines randomly based at least in part on at least one word line of the plurality of word lines of the block being unprogrammed.

Aspect 11: The method, apparatus, or non-transitory computer-readable medium of any of aspects 4 through 10, further including operations, features, circuitry, logic, means, or instructions, or any combination thereof for selecting, from among a plurality of word lines of the block, the one or more word lines randomly based at least in part on the one or more word lines being adjacent to a word line selected during the access operation.

Aspect 12: The method, apparatus, or non-transitory computer-readable medium of any of aspects 4 through 11, further including operations, features, circuitry, logic, means, or instructions, or any combination thereof for selecting, from among a plurality of word lines of the block, the one or more word lines based at least in part on the one or more word lines being maintained in a list of word lines stored at the memory device.

Aspect 13: The method, apparatus, or non-transitory computer-readable medium of any of aspects 1 through 12, further including operations, features, circuitry, logic, means, or instructions, or any combination thereof for comparing, based at least in part on performing the read disturb scan, a quantity of errors of the block with a threshold quantity of errors and folding the block based at least in part on the quantity of errors satisfying the threshold quantity of errors.

Aspect 14: The method, apparatus, or non-transitory computer-readable medium of any of aspects 1 through 13, further including operations, features, circuitry, logic, means, or instructions, or any combination thereof for comparing, based at least in part on performing the scan operation, a quantity of errors of the block with a threshold quantity of errors and reinitiating the scan operation for a second block of the memory device based at least in part on the quantity of errors failing to satisfy the threshold quantity of errors.

Aspect 15: The method, apparatus, or non-transitory computer-readable medium of any of aspects 1 through 14, further including operations, features, circuitry, logic, means, or instructions, or any combination thereof for generating a positive random value that is less than or equal to the frequency, where the threshold associated with the frequency corresponds to the positive random value.

Aspect 16: The method, apparatus, or non-transitory computer-readable medium of any of aspects 1 through 15, where performing the access operation includes operations, features, circuitry, logic, means, or instructions, or any combination thereof for receiving a read command for a page of the block and performing a read operation for the page of the block based at least in part on receiving the read command.

Aspect 17: The method, apparatus, or non-transitory computer-readable medium of any of aspects 1 through 16, where the one or more operating parameters includes a program erase count, or a temperature of the memory device, or both.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of these are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device, comprising:
one or more memory devices; and
processing circuitry coupled with the one or more memory devices and configured to cause the memory device to:
initiate a scan operation for a block of the memory device;
perform an access operation on the block based at least in part on one or more operating parameters associated with the memory device;
adjust a counter associated with the block based at least in part on performing the access operation; and
perform, as part of the scan operation, a read disturb scan for the block based at least in part on the counter satisfying a threshold, wherein the threshold is associated with a frequency for the scan operation, and wherein the one or more operating parameters comprise the frequency.

2. The memory device of claim 1, wherein the processing circuitry is further configured to cause the memory device to:
compare a temperature of the memory device with a threshold temperature, wherein initiating the scan operation is based at least in part on the temperature of the memory device satisfying the threshold temperature.

3. The memory device of claim 1, wherein the processing circuitry is further configured to cause the memory device to:
perform a test operation on the memory device, the test operation associated with a quantity of errors of the memory device, wherein initiating the scan operation is based at least in part on the quantity of errors of the memory device detected during the test operation satisfying a threshold quantity of errors.

4. The memory device of claim 1, wherein performing the read disturb scan comprises the processing circuitry configured to cause the memory device to:
scan one or more pages for one or more word lines of the block, wherein the one or more pages are scanned based at least in part on a priority rating of the one or more pages; and
identify a quantity of errors associated with voltage thresholds of the one or more pages based at least in part on the scanning.

5. The memory device of claim 4, wherein the priority rating of the one or more pages is based at least in part on a quantity of bits stored in one or more memory cells associated with the one or more word lines.

6. The memory device of claim 5, wherein scanning the one or more pages comprises the processing circuitry configured to cause the memory device to:
scan a top page and a lower page of each of the one or more word lines based at least in part on the one or more memory cells being quad-level cells.

7. The memory device of claim 5, wherein scanning the one or more pages comprises the processing circuitry configured to cause the memory device to:
scan an extra page and a lower page of each of the one or more word lines based at least in part on the one or more memory cells being triple-level cells.

8. The memory device of claim 5, wherein scanning the one or more pages comprises the processing circuitry configured to cause the memory device to:
scan an upper page and a lower page of each of the one or more word lines based at least in part on the one or more memory cells being multi-level cells.

9. The memory device of claim 4, wherein the processing circuitry is further configured to cause the memory device to:
select, from among a plurality of word lines of the block, the one or more word lines randomly based at least in part on a second quantity of errors previously detected at the one or more word lines.

10. The memory device of claim 4, wherein the processing circuitry is further configured to cause the memory device to:
select, from among a plurality of word lines of the block, the one or more word lines randomly based at least in part on at least one word line of the plurality of word lines of the block being unprogrammed.

11. The memory device of claim 4, wherein the processing circuitry is further configured to cause the memory device to:
select, from among a plurality of word lines of the block, the one or more word lines randomly based at least in part on the one or more word lines being adjacent to a word line selected during the access operation.

12. The memory device of claim 4, wherein the processing circuitry is further configured to cause the memory device to:
select, from among a plurality of word lines of the block, the one or more word lines based at least in part on the one or more word lines being maintained in a list of word lines stored at the memory device.

13. The memory device of claim 1, wherein the processing circuitry is further configured to cause the memory device to:
compare, based at least in part on performing the read disturb scan, a quantity of errors of the block with a threshold quantity of errors; and
fold the block based at least in part on the quantity of errors satisfying the threshold quantity of errors.

14. The memory device of claim 1, wherein the processing circuitry is further configured to cause the memory device to:
compare, based at least in part on performing the scan operation, a quantity of errors of the block with a threshold quantity of errors; and
reinitiate the scan operation for a second block of the memory device based at least in part on the quantity of errors failing to satisfy the threshold quantity of errors.

15. The memory device of claim 1, wherein the processing circuitry is further configured to cause the memory device to:
generate a positive random value that is less than or equal to the frequency, wherein the threshold associated with the frequency corresponds to the positive random value.

16. The memory device of claim 1, wherein performing the access operation comprises the processing circuitry configured to cause the memory device to:
receive a read command for a page of the block; and
perform a read operation for the page of the block based at least in part on receiving the read command.

17. The memory device of claim 1, wherein the one or more operating parameters comprises a program erase count, or a temperature of the memory device, or both.

18. A non-transitory computer-readable medium storing code, the code comprising instructions executable by one or more processors to:
initiate a scan operation for a block of a memory device;
perform an access operation on the block based at least in part on one or more operating parameters associated with the memory device;
adjust a counter associated with the block based at least in part on performing the access operation; and
perform, as part of the scan operation, a read disturb scan for the block based at least in part on the counter satisfying a threshold, wherein the threshold is associated with a frequency for the scan operation, and wherein the one or more operating parameters comprise the frequency.

19. The non-transitory computer-readable medium of claim 18, wherein the instructions are further executable by the one or more processors to:
compare a temperature of the memory device with a threshold temperature, wherein initiating the scan operation is based at least in part on the temperature of the memory device satisfying the threshold temperature.

20. The non-transitory computer-readable medium of claim 18, wherein the instructions are further executable by the one or more processors to:
perform a test operation on the memory device, the test operation associated with a quantity of errors of the memory device, wherein initiating the scan operation is based at least in part on the quantity of errors of the memory device detected during the test operation satisfying a threshold quantity of errors.

21. The non-transitory computer-readable medium of claim 18, wherein the instructions to perform the read disturb scan are executable by the one or more processors to:
scan one or more pages for one or more word lines of the block, wherein the one or more pages are scanned based at least in part on a priority rating of the one or more pages; and
identify a quantity of errors associated with voltage thresholds of the one or more pages based at least in part on the scanning.

22. The non-transitory computer-readable medium of claim 21, wherein the priority rating of the one or more pages is based at least in part on a quantity of bits stored in one or more memory cells associated with the one or more word lines.

23. The non-transitory computer-readable medium of claim 22, wherein the instructions to scan the one or more pages are executable by the one or more processors to:
scan a top page and a lower page of each of the one or more word lines based at least in part on the one or more memory cells being quad-level cells.

24. The non-transitory computer-readable medium of claim 22, wherein the instructions to scan the one or more pages are executable by the one or more processors to:
scan an extra page and a lower page of each of the one or more word lines based at least in part on the one or more memory cells being triple-level cells.

25. A method by a memory device, comprising:
initiating a scan operation for a block of the memory device;
performing an access operation on the block based at least in part on one or more operating parameters associated with the memory device;
adjusting a counter associated with the block based at least in part on performing the access operation; and
performing, as part of the scan operation, a read disturb scan for the block based at least in part on the counter satisfying a threshold, wherein the threshold is associated with a frequency for the scan operation, and wherein the one or more operating parameters comprise the frequency.
